(19) United States
(12) Patent Application Publication
(10) Pub. No.: US 2003/0034540 A1
(43) Pub. Date: Feb. 20, 2003

(54) Photodetector, photodetecting device and method for controlling the sensitivity profile of a photodetector

(75) Inventors: Gil Afriat, Colorado Springs, CO (US); James H. Lauffenburger, Colorado Springs, CO (US); Kevin S. Buescher, Colorado Springs, CO (US)

Correspondence Address: SUGHRUE MION ZINN MACPEAK & SEAS, PLLC, 2100 Pennsylvania Avenue, NW, Washington, DC, 20037-3213, US

(73) Assignee: EM MICROELECTRONIC-MARIN SA

(21) Appl. No.: 09/932,462

(22) Filed: Aug. 20, 2001

(51) Int. Cl. H01L 27/14

(52) U.S. Cl. 257/461; 257/431; 257/443; 257/459

(57) ABSTRACT

There is described a method for controlling the sensitivity profile of a photodetector (1; 1a to 1d) comprising at least one well (10; 10a to 10d) of a first conductivity type (e.g. N) formed in a semiconductor substrate (20) of a second conductivity type (e.g. P), this method comprising the steps of determining a desired sensitivity profile for the photodetector, forming at least one diffusion region (15; 15a to 15d) of the first conductivity type in a determined region of the well and/or forming at least one diffusion region (25) of the second conductivity type in the semiconductor substrate adjacent to the well, and connecting said at least one diffusion region of the first or second conductivity type to a positive or negative potential of a reverse-bias voltage applied across said well and said semiconductor substrate.

There is also described a photodetecting device (5) for controlling track and focus of a light beam, such as a laser beam of a CD-ROM or DVD-ROM drive.

### BACKGROUND OF THE INVENTION

The present invention generally relates to photodetectors and photodetecting devices, and in particular to a photodetector and photodetecting device having locally enhanced sensitivity. The term “Sensitivity” refers to the current to optical power conversation ratio of the photodetector.

CD-ROM and DVD-ROM drives are now increasingly being used for retrieving stored data. Such devices typically employ optical pickup devices, or OPIC's, comprising several photodetectors made from bipolar device or simple PN junction diodes.

A CMOS integrated PN junction diode, or photodiode, converts optical power to electrical current and is typically realized by creating a reversed biased PN junction. The PN junction creates a depletion area with an electric field, which separates the photo-generated electron-hole pairs. The photo-generated current can then be picked up and amplified for subsequent processing. The PN junction is conventionally realized by an N-well over a P-type semiconductor substrate or, alternatively, by a P-well over an N-type semiconductor substrate.

In many applications, it is desirable to have a photodetector that exhibits a non-uniform sensitivity profile. If adequately determined, this sensitivity profile can for instance be used to control track and focus of a light beam, such as a laser beam of CD-ROM or DVD-ROM drive.

An aim of the present invention is thus to provide a method for easily controlling the sensitivity profile of a photodetector. Another aim of the present invention is to provide photodetecting structures having at least one region of high sensitivity.

### SUMMARY OF THE INVENTION

A first object of the present invention is a method for controlling the sensitivity profile of a photodetector comprising at least one well of a first conductivity type formed in a semiconductor substrate of a second conductivity type, this method comprising the steps of:

a) determining a desired sensitivity profile for the photodetector;

b) forming at least one diffusion region of the first conductivity type in a determined region of the well and/or forming at least one diffusion region of the second conductivity type in the semiconductor substrate adjacent to the welt; and

c) connecting said at least one diffusion region of the first or second conductivity type to a positive or negative potential of a reverse-bias voltage applied across said well and said semiconductor substrate.

A second object of the present invention is a photodetector comprising a well of a first conductivity type formed in a semiconductor substrate of a second conductivity type, this photodetector further comprising at least one region of higher sensitivity including a diffusion region of the first conductivity type formed in the well and/or a diffusion region of the second conductivity type formed in the semiconductor substrate adjacent to the well.

A third object of the present invention is a photodetecting device for controlling track and focus of a light beam, such as a laser beam of a CD-ROM or DVD-ROM drive, comprising an array of four distinct wells of a first conductivity type formed in a semiconductor substrate of a second conductivity type, this photodetecting device comprising a central region of high sensitivity including at least one diffusion region of the first conductivity type formed in each of the wells and/or at least one diffusion region of the second conductivity type formed in the semiconductor substrate between the wells.

According to a first embodiment of the invention, the well is designed to have a substantially annular shape surrounding a portion of the semiconductor substrate, and a diffusion region of the second conductivity type is formed within this portion of the semiconductor substrate. According to a variant of this first embodiment, at least one diffusion region of the first conductivity type is further formed in the well adjacent to the diffusion region of the second conductivity type.

According to a particularly advantageous embodiment of the invention the portion of the semiconductor substrate surrounded by the well and the diffusion region of the second conductivity type formed within this portion substantially have the shape of a cross. According to a variant of this other embodiment four distinct diffusion regions of the first conductivity type are further formed around and adjacent to the cross-shaped diffusion region of the second conductivity type.

According to the present invention, the sensitivity profile of the photodetector can easily be controlled by simply forming diffusion regions of the first (i.e. N) or second (i.e. P) conductivity type within the well of the photodetector or in the semiconductor substrate adjacent to the well of the photodetector. By combining the effects of both types of diffusion regions, one can easily enhance the photodetector's sensitivity in a desired location of the photodetector. The present invention further has the advantage that the process of forming these diffusion regions is entirely compatible with standard CMOS processes.

### BRIEF DESCRIPTION OF THE DRAWINGS

Other features and advantages of the present invention will be apparent upon reading the following description of various embodiments of the invention, given here purely by way of non-limiting examples made with reference to the following drawings, where:

FIG. 1 shows a photodetector comprising an N-well formed in a P-type semiconductor substrate and including an additional N+ diffusion region formed in the N-well, as well as an additional P+ diffusion region formed in the semiconductor substrate adjacent to the N-well;

FIG. 2 shows a particularly advantageous embodiment of the photodetector according to the present invention comprising an annular-shaped N-well formed in a P-type semiconductor substrate and including an additional cross-shaped P+ diffusion region formed in a portion of the semiconductor substrate within the N-well, as well as additional N+ diffusion regions formed within the N-well around the cross-shaped P+ diffusion region;

FIG. 3 shows a photodetecting device for controlling track and focus of a light beam, such as a laser beam of a CD-ROM or DVD-ROM drive, comprising an array of four distinct N-wells formed in a P-type semiconductor substrate, this photodetecting device comprising a central region of high sensitivity including a cross-shaped P+ diffusion region formed between the N-wells and N+ diffusion regions in each of the N-wells around the P+ diffusion region;

FIG. 4 shows a photodetecting device having a split detector configuration for controlling track of a light beam, such as a laser beam of a CD-ROM or DVD-ROM drive, comprising a pair of adjacent N-wells formed in a P-type semiconductor substrate, this photodetecting device comprising a middle region of high sensitivity including a P+ diffusion region formed between the N-wells and N+ diffusion regions in each of the N-wells on each side of the P+ diffusion region; and

FIG. 5 shows a photodetecting device similar to that of FIG. 3 comprising an array of four distinct N-wells formed in a P-type semiconductor substrate, this photodetecting device comprising a central region of high sensitivity including a cross-shaped P+ diffusion region formed between the N-wells and N+ diffusion regions in each of the N-wells around the P+ diffusion region.

### DETAILED DESCRIPTION OF THE INVENTION

According to the invention, in order to locally enhance the sensitivity of a photodetector, strong local electric fields are created in areas within (or adjacent to) the photodetector. These areas will exhibit higher opto-electronic sensitivity due to the higher electrical field, which separates the photo-generated electron-hole pairs before they recombine.

In order to create these local electric fields within the photodetector, local strong connections to either the positive potential (VBIAS+) or negative potential (VBIAS−, usually ground) of the reverse-bias voltage VBIAS applied across the photodiode are formed. In the case of a photodiode comprising an N-well over a P-type semiconductor substrate, P+ diffusion regions connected to the negative potential of the reverse-bias voltage can be created in the semiconductor substrate within or adjacent to the N-well. This will create local PN junctions within the photodiode with strong electric field across them, and which will exhibit local higher sensitivity.

Alternatively, and according to the same principle, N+ diffusion regions connected to the positive potential of the reverse-bias voltage can be formed within the area of the N-well of the photodiode to create higher local electric field and sensitivity

The same principle is applicable in the case of a photodiode comprising a P-well over an N-type semiconductor substrate.

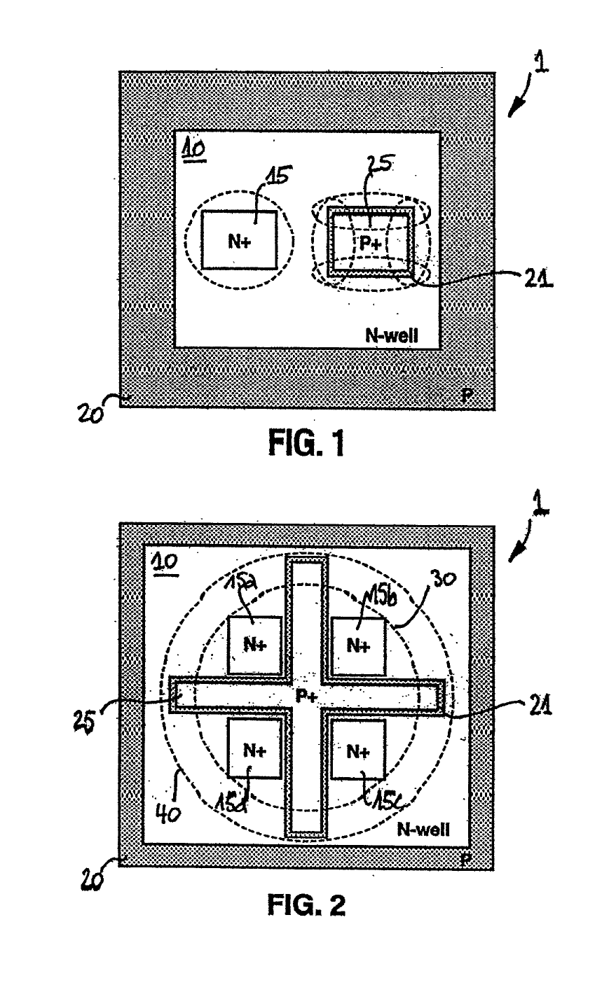

FIG. 1 schematically illustrates how N+ and P+ diffusion regions may be formed within the area of the photodetector to locally enhance its sensitivity. FIG. 1 shows a photodetector, indicated globally by reference numeral 1, comprising an N-well 10 formed in a P-type semiconductor substrate 20.

Local enhancement of the photodetector's sensitivity is achieved by forming an N+ diffusion region 15 within N-well 10 as explained above. Local enhancement of the photodetectors sensitivity can also be achieved by forming a P+ diffusion region 25 in semiconductor substrate 20 adjacent to N-well 10. In FIG. 1, the P+ diffusion region 25 is actually formed within the area of N-well 10. In this case, N-well 10 has a substantially annular shape surrounding a portion 21 of semiconductor substrate 20, and the P+ diffusion region 26 is formed within that portion 21 of semiconductor substrate 20.

It will be appreciated that the effect of N+ and P+ diffusion regions can be combined to achieve even greater sensitivity enhancement. FIG. 2 illustrates a particularly advantageous embodiment of the present invention wherein N+ and P+ diffusion regions are combined to locally enhance the photodetector's sensitivity.

FIG. 2 again shows a photodiode 1 comprising an N-well 10 formed in a P-type semiconductor substrate 20. N-well 10 substantially has an annular shape and is provided with a central opening 11. Within this central opening 11, a portion 21 of semiconductor substrate 20 is exposed. In a similar way to the example of FIG. 1, a P+ diffusion region 25 is formed in semiconductor substrate 20 within portion 21 adjacent to N-well 10. In addition, N+ diffusion regions 15a, 15b, 15c, 15d are formed within N-well 10 around and adjacent to P+ diffusion region 25.

FIG. 2 shows four distinct N+ diffusion regions disposed around P+ diffusion region 25. It will however be appreciated that a single N+ diffusion region completely surrounding the central P+ diffusion region 25 could be formed. As a matter of fact, N+ and P+ diffusion regions could take any appropriate form and could be combined in various different ways to achieve the desired sensitivity profile.

In particular, P+ diffusion region 25 may advantageously take the shape of a cross as illustrated in FIG. 2. N+ diffusion regions 15a to 15d may then be formed within each of the four arms of the cross-shaped P+ diffusion region 26.

By changing the size and dimension of the respective N+ and P+ diffusion regions one can easily vary the level of sensitivity enhancement. As shown in FIG. 2, the arms of the cross-shaped P+ diffusion region 25 can be made much longer than the width of the N+ diffusion regions 15a to 15d.

Accordingly, the photodetector will exhibit a very high local sensitivity in the center, as schematically illustrated by inner circle 30, and a less enhanced sensitivity around the center, as schematically illustrated by outer circle 40. It will be appreciated that the sensitivity of the photodetector is higher at the center and decreases as one moves away from the center of the photodetector.

The structure of FIG. 2 may advantageously be used to track the position of a light beam on the photodetector's sensing area more precisely and accurately than this would be the case with a conventional photodiode.

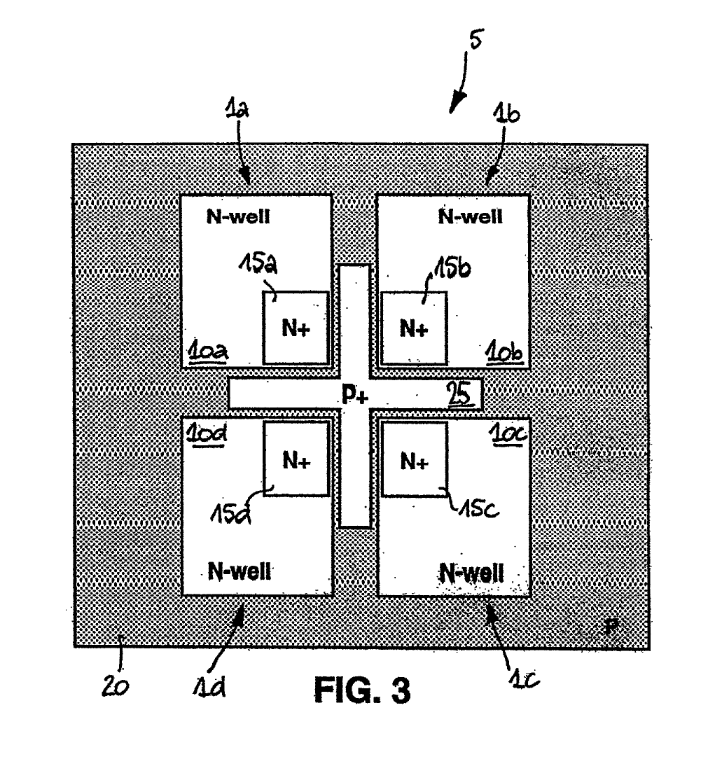

The above-described enhancing scheme can also be applied to several photodetectors, which can then be combined together. FIG. 3 for instance shows a particularly advantageous photodetecting device Which can be used to control track and focus of a light beam, such as the laser beam of a CD-ROM or DVD-ROM drive. This photodetecting device, indicated globally by reference numeral 5, has a quad detector configuration and essentially comprises a regular array of four distinct photodetectors 1a to 1d each comprising an N-Well 10a, 10b, 10c and 10d, respectively, formed in a P-type semiconductor substrate 20. A P+ diffusion region 25, advantageously having the shape of cross, is formed in semiconductor substrate 20 between N-wells 10a to 10d. Additional N+ diffusion regions 15a, 15b, 15c and 15d are respectively formed in each of the wells 10a to 10d so as to further enhance the sensitivity of the photodetecting device in the center area of the device.

It will be appreciated that N+ diffusion regions 15a to 15d could be made larger or could even be discarded. The photodetecting device would still have a higher sensitivity close to the center of the device due to the P+ diffusion region 25, but it will be log enhanced. Similarly, P+ diffusion region 29 could be discarded and the photodetecuing device 5 could only be provided with N+ diffusion regions 15a to 15d in the wells 10a to 10d.

As already mentioned, the photodetecting device 5 of FIG. 3 can advantageously be used to control track and focus of a laser beam of a CD-ROM or DVD-ROM drive. Indeed, each photodetector 1a to 1d will provide a signal indicative of the position of the light beam with respect to the center of the photodetecting device, thereby providing information to correct the orientation of the laser beam or to adjust its focus.

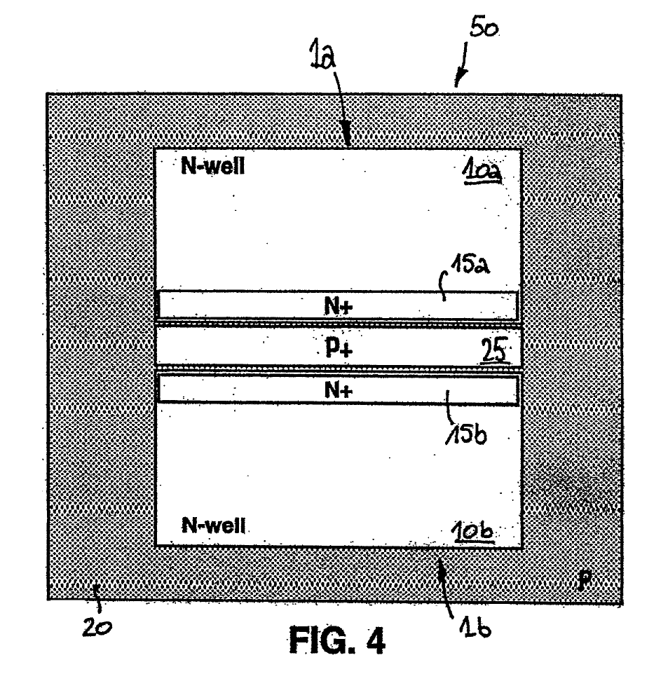

FIG. 4 shows a photodetecting device having a split detector configuration for controlling track of a light beam, such as a laser beam of a CD-ROM or DVD-ROM drive. This photodetecting device, indicated globally be reference numeral 50, comprises a pair of adjacent photodetectors 1a and 1b each including an N-well 10a, 10b formed in a P-type semiconductor substrate 20. This photodetecting device 50 comprises a middle region of high sensitivity including a P+ diffusion region 25 formed between the N-wells 10a, 10b and N+ diffusion regions 15a, 15b in each of the N-wells 10a, 10b on both side of the P+ diffusion region 25.

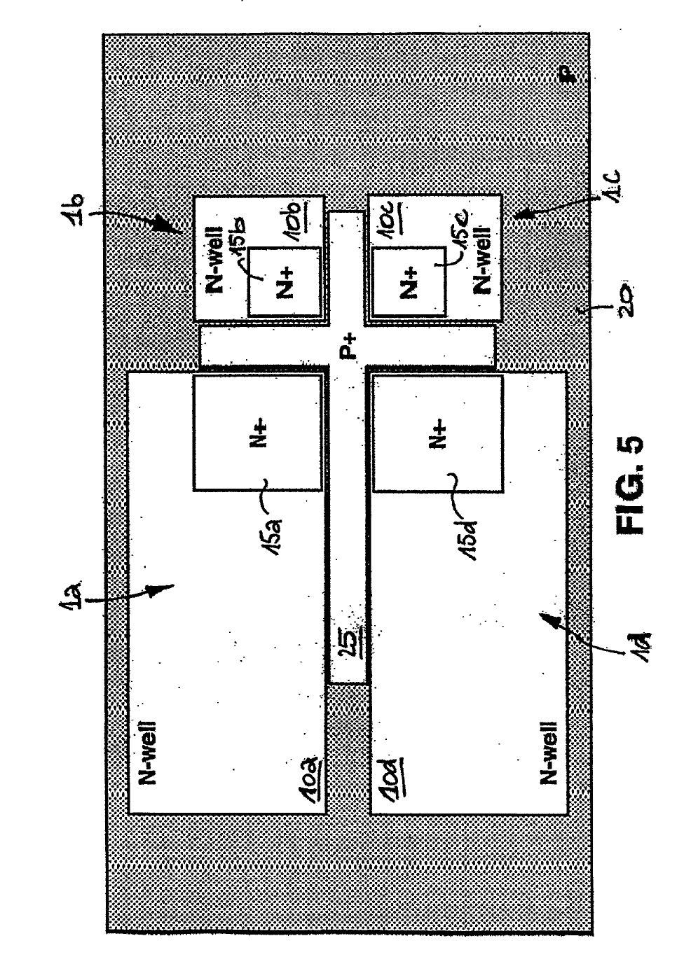

FIG. 5 shows a photodetecting device similar to that of FIG. 3 comprising an array of four distinct photodetectors 1a to 1d each comprising an N-well 10a to 10d formed in a P-type semiconductor substrate 20, this photodetecting device again comprising a central region of high sensitivity including a cross-shaped P+ diffusion region 25 formed between the N-wells 10a to 10d and N+ diffusion regions 15a to 15d in each of the N-wells around the P+ diffusion region 25. FIG. 5 illustrates that the wells and/or diffusion regions can take any desired size, dimension or shape.

While the invention has been described with reference to specific embodiments, it will be appreciated that many modifications and/or improvements could be made by those skilled in the art without departing from the scope of the invention defined by the annexed claims. For instance, instead of being an N-well over a P-type semiconductor substrate, the photodetector could be a P-well over an N-type semiconductor substrate. Moreover, the N+ or P+ diffusion regions created within the photodetector's area could take any other shape, size and dimensions than those illustrated.

What is claimed is:

1. A method for controlling the sensitivity profile of a photodetector comprising at least one well of a first conductivity type formed in a semiconductor substrate of a second conductivity type, said method comprising the steps of:
a) determining a desired sensitivity profile for said photodetector;
b) forming at least one diffusion region of the first conductivity type in a determined region of said well and/or forming at least one diffusion region of the second conductivity type in said semiconductor substrate adjacent to said well; and
c) connecting said at least one diffusion region of the first or second conductivity type to a positive or negative potential of a reverse-bias voltage applied across said well and said semiconductor substrate.

2. The method of claim 1, wherein said well substantially has an annular shape and surrounds a portion of said semiconductor substrate, said step (b) comprising the step of forming a diffusion region of the second conductivity type within said portion of the semiconductor substrate.

3. The method of claim 2, further comprising the step of forming at least one diffusion region of the first conductivity type in said well adjacent to said diffusion region of the second conductivity type.

4. The method of claim 2, wherein said portion of the semiconductor substrate and said diffusion region of the second conductivity type formed within said portion substantially have the shape of a cross.

5. The method of claim 2, wherein said portion of the semiconductor substrate and said diffusion region of the second conductivity type formed within said portion substantially have the shape of a cross, said method further comprising the step of forming four distinct diffusion regions of the first conductivity type around and adjacent to said cross-shaped diffusion region of the second conductivity tape.

6. The method of claim 3 or 4, wherein said diffusion region of the first conductivity type completely surrounds said diffusion region of the second conductivity type.

7. The method of claim 1, comprising the steps of forming an array of four distinct wells of the first conductivity type in said semiconductor substrate and forming a diffusion region of the first conductivity type in each of said wells, said diffusion region being located in a central region of said array.

8. The method of claim 7, further comprising the step of forming a diffusion region of the second conductivity type between said wells.

9. The method of claim 1, comprising the steps of forming an array of four distinct wells of the first conductivity type in said semiconductor substrate and forming a diffusion region of the second conductivity type between said wells.

10. The method of claim 7, further comprising the step of forming a diffusion region of the first conductivity type in each of said wells, said diffusion region being located in a central region of said array.

11. A photodetector comprising a well of a first conductivity type formed in a semiconductor substrate of a second conductivity type, said photodetector further comprising at least one region of higher sensitivity including a diffusion region of the first conductivity type formed in said well and/or a diffusion region of the second conductivity type formed in said semiconductor substrate adjacent to said well, said at leant one diffusion region of the first or second conductivity type being connected either to a positive or negative potential of a reverse-bias voltage applied across said well and said semiconductor substrate.

12. The photodetector of claim 11, wherein said well substantially has an annular shape and surrounds a portion of said semiconductor substrate said photodetector comprising a diffusion region of the second conductivity type formed within said portion of the semiconductor substrate.

13. The photodetector of claim 12, further comprising at least one diffusion region of the first conductivity type formed in said well adjacent to said diffusion region of the second conductivity type.

14. The photodetector of claim 12, wherein said portion of the semiconductor substrate and said diffusion region of the second conductivity type formed within said portion substantially have the shape of a cross.

15. The photodetector of claim 12, wherein said portion of the semiconductor substrate and said diffusion region of the second conductivity type formed within said portion substantially have the shape of a cross, said photodetector further comprising four distinct diffusion regions of the first conductivity type disposed around and adjacent to said cross-shaped diffusion region of the second conductivity type.

16. The photodetector of claim 13 or 14, wherein said diffusion region of the first conductivity type completely surrounds said diffusion region of the second conductivity type.

17. A photodetecting device for controlling track and/or focus of a light beam, such as a laser beam of a CD or DVD drive, comprising an array of four distinct wells of a first conductivity type formed in a semiconductor substrate of a second conductivity type, said photodetecting device comprising a central region of high sensitivity including at least one diffusion region of the first conductivity type formed in each of said wells and/or at least one diffusion region of the second conductivity type formed in said semiconductor substrate between said wells, said at least one diffusion region of the first or second conductivity type being connected either to a positive or negative potential of a reverse-bias voltage applied across said well and said semiconductor substrate.

18. The photodetecting device of claim 17, comprising a diffusion region of the second conductivity type formed in said semiconductor substrate between said wells, said diffusion region of the second conductivity type substantially having the shape of a cross.

19. The photodetecting device of claim 18, further comprising a diffusion region of the first conductivity type in each of said wells disposed around and adjacent to said diffusion region of the second conductivity type.

20. A photodetecting device for controlling track of a light beam, such as a laser beam of a CD or DVD drive, comprising a pair of adjacent wells of a first conductivity type formed in a semiconductor substrate of a second conductivity type, said photodetecting device comprising a middle region of high sensitivity including at least one diffusion region of the first conductivity type formed in each of said wells and/or at least one diffusion region of the second conductivity type formed in said semiconductor substrate between said wells, said at least one diffusion region of the first or second conductivity type being connected either to a positive or negative potential of a reverse-bias voltage applied across said well and said semiconductor substrate.

21. The photodetecting device of claim 20, comprising a diffusion region of the second conductivity type formed in said semiconductor substrate between said wells, and first and second diffusion region of the first conductivity type in each of said wells disposed on both sides of said diffusion region of the second conductivity type.
